(19) United States
(12) Patent Application Publication
(10) Pub. No.: US 2019/0131997 A1
(43) Pub. Date: May 2, 2019

(54) BOOTSTRAPPED HIGH-SPEED SUCCESSIVE APPROXIMATION ANALOG TO DIGITAL CONVERTER

(71) Applicant: AVAGO TECHNOLOGIES INTERNATIONAL SALES PTE. LIMITED, Singapore (SG)

(72) Inventors: Yong LIU, Irvine, CA (US); Delong CUI, Tustin, CA (US); Jun CAO, Irvine, CA (US)

(73) Assignee: AVAGO TECHNOLOGIES INTERNATIONAL SALES PTE. LIMITED, Singapore (SG)

(21) Appl. No.: 15/796,300

(22) Filed: Oct. 27, 2017

(51) Int. Cl. H03M 1/46

(52) U.S. Cl. CPC H03M 1/46

(57) ABSTRACT

Apparatus, system and method for driving asynchronous digital-to-analog circuits are provided. An apparatus including circuitry configured to receive an analog signal, determine a comparison signal based on the analog signal, convert the comparison signal to a digital signal, generate a comparison reset signal after a preset delay, determine a final comparison signal based on the digital signal, convert the final comparison signal to a final digital signal, and output the final comparison signal. The circuitry successively approximates the digital signal using a binary search.

### FIELD OF DISCLOSURE

The present disclosure relates generally to a successive approximation analog to digital converter having a shortened clock pulse width.

### BACKGROUND

Analog to Digital converter (ADC)-based receivers continue to demand higher speeds and higher resolution for data transfer. A type of analog to digital converter is a successive approximation analog to digital converter (SAR ADC). The SAR ADC can achieve higher speeds through the use of high-speed clocking circuits. in the meantime, the power of the clocking and Finite State Machine (FSM) needs to be low, especially for high-speed high-resolution receivers where there are tens of, or even hundreds of, interleaving SAR ADC's. Conventional SAR ADCs use asynchronous clocking scheme due to power efficiency. However, the asynchronous clocks have both the rising and falling edges generated through a comparator and the same logic circuit. In particular, the falling edge of the SAR ADC is generated through comparator reset. Thus, the clock pulse width in an asynchronous clocking scheme is limited by the performance of a comparator and the related logic circuit.

The foregoing “Background” description is for the purpose of generally presenting the context of the disclosure. Work of the inventors, to the extent t is described in this background section, as well as aspects of the description which may not otherwise qualify as prior art at the time of filing, are neither expressly or impliedly admitted as prior art against the present invention.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 is a schematic that illustrates a successive approximation analog to digital converter;

FIG. 2 is a timing diagram for the successive approximation analog to digital converter of FIG. 1;

FIG. 3 is a timing diagram for clock generation in the successive approximation analog to digital converter of FIG. 1;

FIG. 4 is a schematic that shows a successive approximation analog to digital converter having a clock logic circuit according to an exemplary aspect of the disclosure;

FIG. 5 is an exemplary timing diagram for the successive approximation analog to digital converter of FIG. 4;

FIG. 6 is a block diagram of the self-generated clock circuit of FIG. 4;

FIG. 7 is a schematic that shows a clock logic circuit according to an exemplary aspect of the disclosure; and

FIG. 8 is an exemplary timing diagram of the clock logic circuit of FIG. 7.

### DETAILED DESCRIPTION

Referring now to the drawings, wherein like reference numerals designate identical or corresponding parts throughout several views, the following description relates to multiplexing circuits for use in digital to analog converter based transmitters.

High-speed Analog to Digital converters (ADC) may be used in data communication systems, instrumentation or control systems. Successive approximation analog to digital converters have demonstrated outstanding bandwidth and superior energy efficiency. However, to achieve faster speeds, the successive approximation (SAR) analog to digital converter (ADC) needs high-speed clocking circuits and fast timing schemes to support the SAR operations. In addition, it is desired to keep the power of the clocking circuits lo

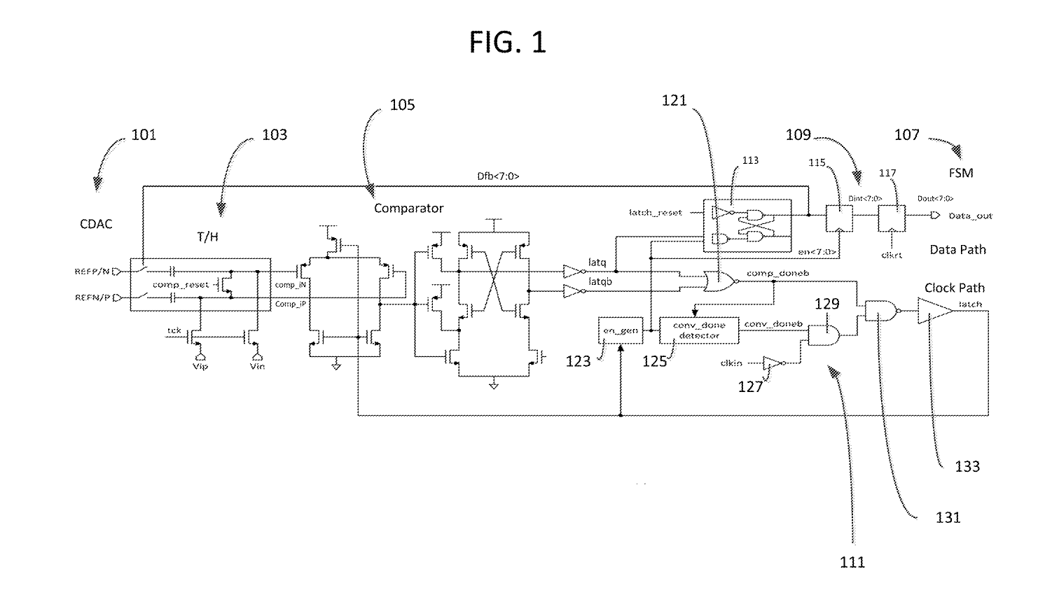

An asynchronous SAR ADC is illustrated in FIG. 1. Without loss of generality, an 8-bit SAR ADC is used as an example in FIG. 1. The SAR DAC includes a switched track and hold circuit (T/H) 103, a capacitive digital-to-analog converter (CDAC) 101, a comparator 105 and a finite state machine (FSM) 107. The switched track and hold circuit (T/H) 103 samples the input analog signal and holds it for a period so that successive comparisons are performed. The comparator 105 performs a comparison of the differential signal stored on the comparator input nodes. Based on the comparison result, FSM 107 generates both internal clock signal and output data signal: the internal clock signal is used for the SAR ADC operation; the output data signal is the converted digital output. in the meantime, after each comparison, the data signal is sent to CDAC 101 to charge or discharge (depending on the comparison result) the input nodes of the comparator 105. The internal clock signal is generated in a clock path circuit 111 of FSM 107. Comparator 105 outputs either a signal latq or a signal latqb which are handled by the clock path circuit 111. The previous sampled signal is fed back by a data path circuit 109. Also, the final converted digital bits are output from the data path circuit 109. The internal clock signal is used to reset the comparator 105 and start a new comparison operation. The data path circuit 109 includes a latch circuit 113, an enumeration circuit 115 and a data retiming circuit 117. The clock path circuit 111 has logic for detecting when the comparison in the comparator 105 is completed, detecting when conversion of a number of bits is completed and sending a clock signal to the comparator 105. The clock path circuit 111 may include a NOR gate 121, a NAND gate 131, a buffer 133, an inverter 127, an AND gate 129, as well as an enable signal generation circuit 123, and a conversion completion detector circuit 125. The comparator output signals are sent through the clock path 111 undergo a delay by way of three gates. First, the signal is passed through a NOR gate 121. The resulting signal is passed through gate 131 and finally through buffer 133 to output the internal clock signal. The NOR gate 121 outputs signal comp_doneb that indicates if the comparator 105 has finished comparison. The enable signal generation circuit 123 counts the number of comparisons and generates enable signals to the conversion end detector 125. The conversion completion detector circuit 125 generates the conversion complete signal conv_doneb to reset operation of the SAR ADC. An external SAR ADC clock input signal clkin is provided to an inverter gate 127. A gate 129 for indicating the end conversion of the number of bits is provided with signals from the conversion complete detector 125 and the inverter gate 127.

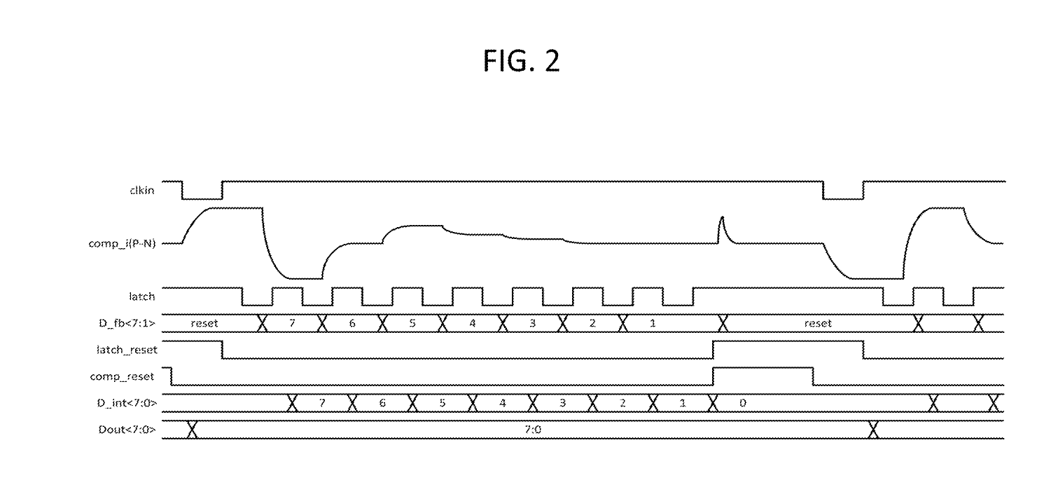

FIG. 2 illustrates a timing diagram for the asynchronous SAR ADC of FIG. 1. Signal clkin is the input clock signal of the SAR ADC: when it is low, T/H 103 tracks the analog input signal; when it is high, T/H 103 holds the input signal on the capacitor at the input nodes of the comparator 105, comp_iP and comp_iN and successive approximation comparisons are performed to generate digital output data Dout<7:0>. First, the SAR ADC internal clock signal latch falls from high to low, which enables the comparator 105 to compare the input signal comp_i(P-N). The comparator 105 generates output signal based on the polarity of comp_i(P-N). The comparator output signal is sent to both the data path 109 and the clock path 111. In the data path 109, the latch 113 generates the first bit D_fb<7>. D_fb<7> goes to the CDAC 101 and applies charge onto signal comp_iP and comp_iN accordingly: if D_fb<7> is high, the comparator input is decreased and if D_fb<7> is low, the comparator input is increased. At the same time, the comparator output signal is also sent to the clock path 111. After the clock path 111, the internal clock signal latch changes from low to high to reset the comparator 105. The rising edge of clock signal latch also retimes signal D_fb<7> in the data retiming circuit 115 to generate data D_int<7>. After the comparator 105 is completely reset, its differential output signals both become low, which in turn makes the clock signal latch change from high to low. This starts the second comparison and the SAR operation repeats in the same way as the first comparison. In the end, when all the 7 comparisons are done, the reset signal of latch 113 latch_reset and the reset signal of T/H 103 comp_reset become high, so that the latch 113 and T/H 103 are reset. When the next input clock clkin falling edge comes, the D_int<7:0> are retimed by the data retiming circuit 117 to generate the SAR ADC output data Dout<7:0>.

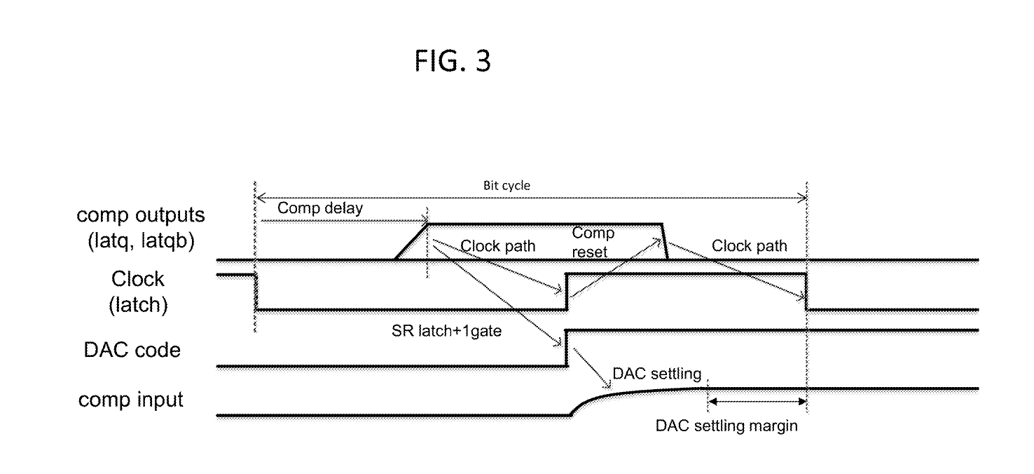

FIG. 3 illustrates a timing diagram illustrating detailed signal timings in the data path 109 and the clock path 111. As illustrated in the timing diagram of FIG. 3, both the rising and falling edges of the clock signal, latch, are generated by the comparator output signals, latq and laqb. In the timing diagram of FIG. 3, initially, both latq and latqb are ‘0’ and the internal clock signal, latch, stays at ‘0’. Then, the comparator 105 starts data comparison, over a comparison delay (Comp delay), and one of the two signals, latq and latqb, becomes ‘1’ and the other stays at ‘0’. The signals latq and latqb are input to gate 121 and gates 131 and 133, over a clock delay (Clock path), The clock signal becomes ‘1’, which resets the two comparator output signals latq and latqb to ‘0’, over comparator reset period, (Comp reset). After a delayed time period (Clock path), the clock signal changes from ‘1’ to ‘0’. Subsequently, the pulse width of the clock signal includes the delay during the comparator reset period and the delay during the clock period.

In particular, the latq and laqb signals that are sent through the clock path 111 undergo a delay by way of three gates. Either the latq or latqb signal is passed through a NOR gate 121. The resulting signal is passed through gate 131 and finally through buffer 133 to output the internal clock signal. The clock speed of the SAR ADC may be improved by reducing the time needed to reset the comparator. One way to make the comparator reset faster may be by making the reset transistor larger. However, this results in an increase in the comparator power consumption and may also make the comparison phase longer due to more parastic capacitance introduced by the larger reset transistor, which slows the overall SAR operation speed.

An exemplary aspect of the present disclosure is a clock path circuit that includes a shortened clock path delay. Instead of generating the clock falling edge through the comparator reset and the clock logic circuit, the clock pulse width may be determined based on a preset delay. The preset delay may be adjusted to meet timing requirements for various processes, voltage and temperature.

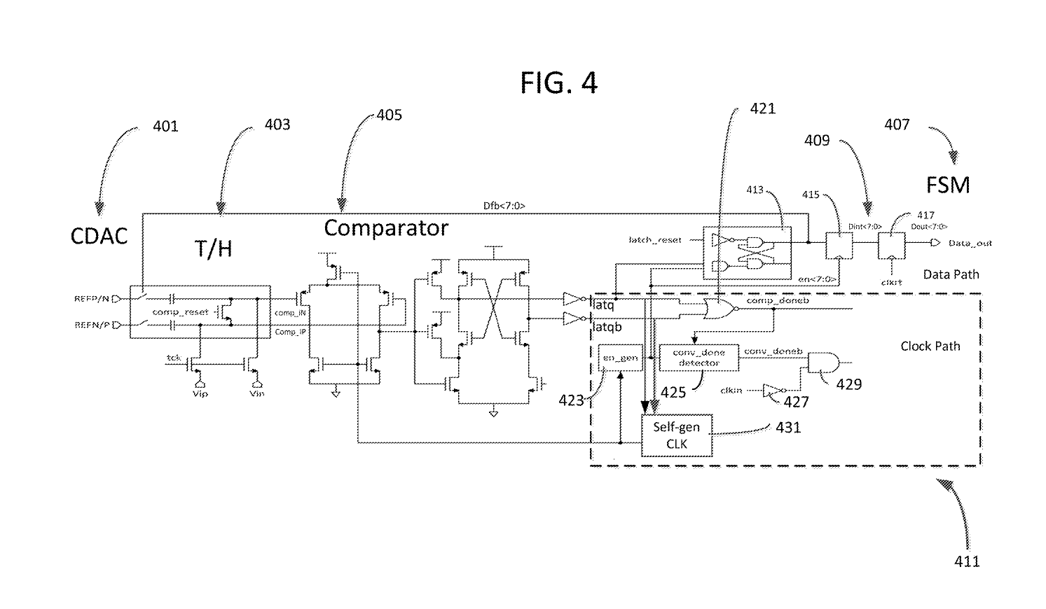

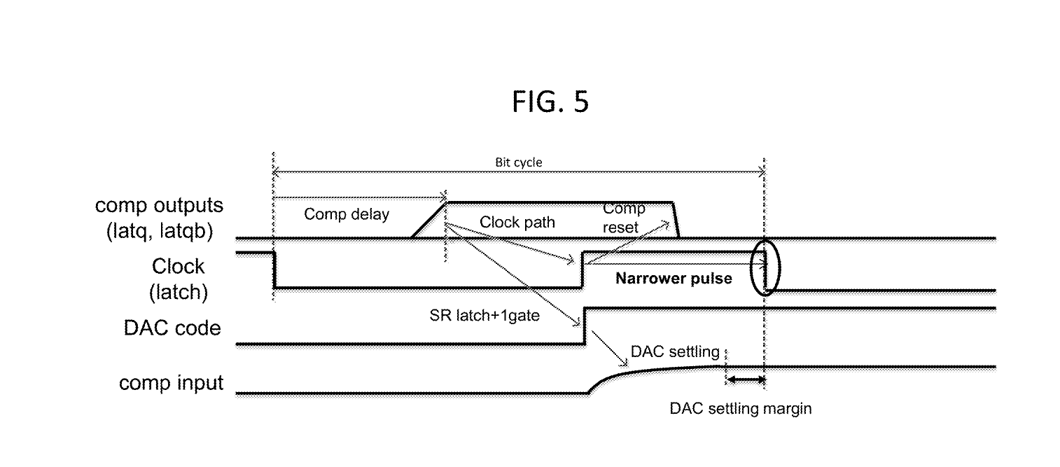

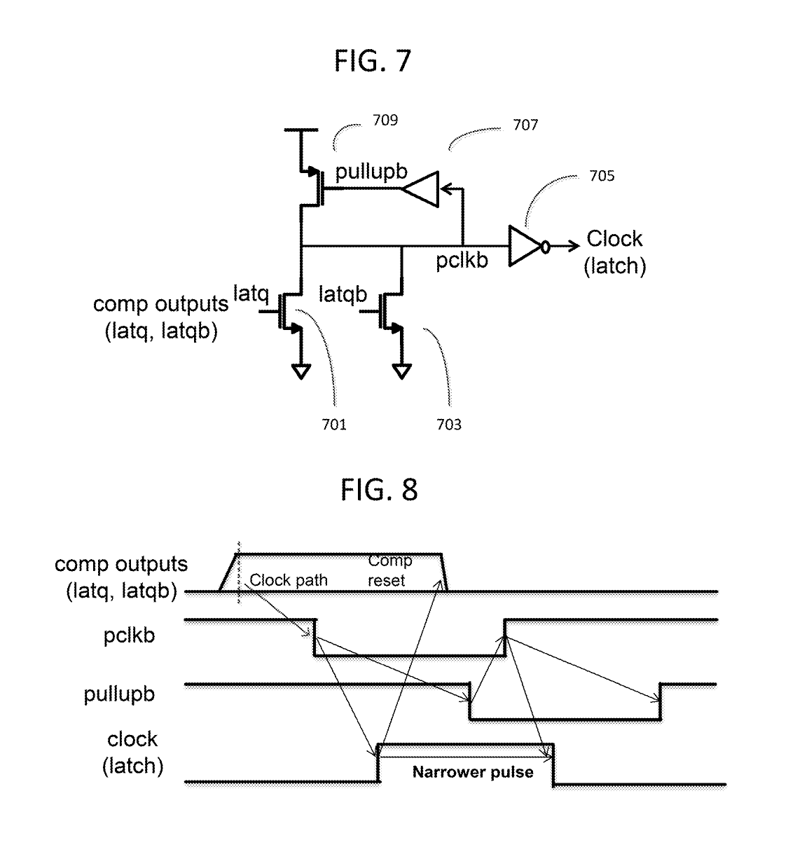

FIG. 4 illustrates an exemplary embodiment of a SAR ADC 400 having a shortened clock path. The SAR ADC 400 may include a digital-to-analog converter (CDAC 401) with a switched track and hold circuit 403, a comparator 405, and a finite state machine (FSM 407). The FSM 407 may include a data path 409 and a clock path 411. An internal clock signal for the comparator 405 may be generated in the clock path 411 of the FSM 407. The internal clock signal for the comparator 405 may be generated by the self-generated clock circuit 431 from the comparator output signals latq and latqb. In this way, as illustrated in the timing diagram in FIG. 5, the falling edge of the clock signal is generated from its own rising edge. In other words, the pulse width of the clock signal can be shortened, as it is no longer limited by the delay in the clock path. An enable signal generation circuit 423, conversion complete detector 425, inverter gate 427, and gate 429 are used to indicate an end of a number of bits converted from the original analog signal. FIG. 4 includes the features in the SAR ADC in FIG. In addition, in the exemplary SAR ADC embodiment, the falling edge of the internal clock signal is generated through self-generation clock circuit 431 and the delay is only 1 gate (shown in FIG. 7 and FIG. 8). In contrast, the time delay to generate the falling edge of the internal clock signal in FIG. 1 is 3 gates. This 2 gate delay reduction is significant since there are 8 comparison cycles in a 8bit SAR ADC, which means that in total, 16 gate delays are reduced for the complete SAR operation. That significantly improves the SAR ADC speed without sacrifice of power. Since the internal clock pulse width is shortened, the DAC settling margin is also shortened as illustrated in FIG. 5. After the DAC code is updated, the charge is introduced to the comparator input and it takes time for the comparator input signal to settle down before the next falling edge of the internal clock signal comes. The DAC settling margin is defined as the time delay between the DAC settles and the falling edge of the internal clock signal. The shorter DAC settling margin is acceptable since in most SAR ADCs, over range protection technique is applied to guarantee correct operation of SAR ADC even when the DAC is not completely settled (especially the first several bits).

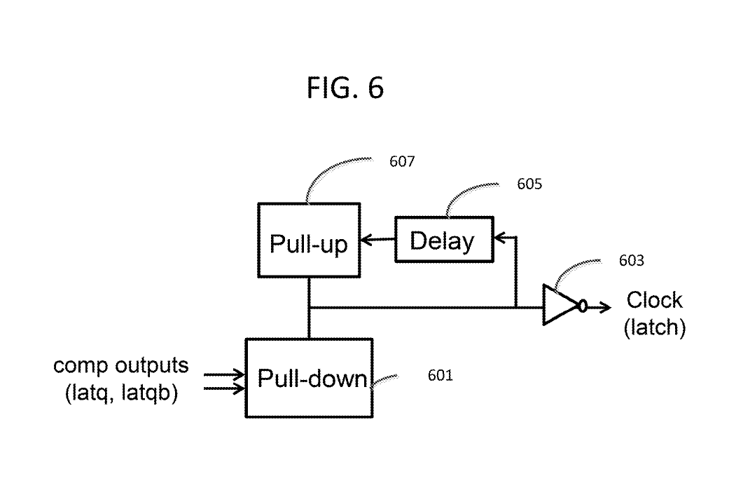

FIG. 6 is a block diagram of the self-generated clock circuit 431 of FIG. 4. The comparator output signals latq and latqb generate the rising edge of clock signals through one pull-down block 601 and an inverter gate 603. The falling edge of the clock signal is generated through a delay cell 605 and a pull-up block 607. The self-generated clock circuit can be implemented as an inverse version of the example shown in FIG. 6: the pull-down block and pull-up block are swapped so that the rising edge and the falling edge of the clock signal are swapped as well. The pull-down block 601 may be any circuit that changes an input voltage from one level to a predetermined level that is lower than the input voltage. The pull-up block 607 may be any circuit that changes an input voltage from one level to a predetermined level that is higher than the input voltage. The delay cell 605 may be any circuit that may temporarily store an input voltage for a predetermined period before outputting the voltage.

FIG. 7 is a schematic of the self-generated clock circuit of FIG. 6. In FIG. 6, the pull-down block 601 may be implemented with two NMOS transistors 701, 703. The pull-up block 607 may be implemented with a PMOS transistor 709. The clock signal, latch, is output from inverter 705. The delay cell 605 may be implemented by buffer 707. As can be appreciated, other implementations are possible with departing from the scope of the present disclosure. For example the transistors 701, 703 may be PMOS, NPN, PNP, or any other transistor type configured to amplify electric power.

FIG. 8 is a timing diagram of relevant signals of the comparator 405 and clock path 411. Initially, latq=latqb=‘0’, pullupb=‘1’, pclkb=‘1’, clock, latch=‘0’. Then, latq and latqb become ‘01’ or ‘10’, depending on the comparator input. Next, pclkb becomes ‘0’ and clock, latch, becomes ‘1’. The comparator enters reset phase. After certain reset delay (Comp reset), latq and latqb become ‘00’. In the meantime, after a predetermined delay through buffer 705, pullupb becomes ‘0’, which pulls up pclkb to ‘1’. Then clock, latch, becomes ‘0’. After the predetermined delay, pullupb becomes ‘1’ again. In another exemplary aspect, in order to more reliably keep pclkb at ‘1’, a weak pullup PMOS transistor may be added in the circuit. The clock pulse delay in the SAR DAC of FIG. 4 includes the reset delay to set latq and latqb back to zero and the delay preset by a delay cell 605, such as buffer 707. The adjustable delay brought about by the delay cell 605 enables a much shorter delay than that in the clock path 111 in the scheme of FIG. 1. The shorter delay is partially due to a clock path 111 that does not include gate 131 and gate 133.

An example of the present disclosure has been implemented as an 8-bit 700 MS/s SAR analog-to-digital converter that has been fabricated using a 16 nm CMOS process. The clock pulse of the example showed a reduction of more than 20%.

A system which includes the features in the foregoing description provides numerous advantages.

Numerous modifications and variations are possible in light of the above teachings. It is therefore to be understood that within the scope of the appended claims, the invention may be practiced otherwise than as specifically described herein.

Thus, the foregoing discussion discloses and describes merely exemplary embodiments of the present invention. As will be understood by those skilled in the art, the features of the present disclosure may be embodied in other specific fowls without departing from the spirit or essential characteristics thereof Accordingly, the present disclosure is merely illustrative, and not limiting of the scope of the novel features described herein, as well as other claims. The disclosure, including any readily discernible variants of the teachings herein, defines, in part, the scope of the foregoing claim terminology such that no inventive subject matter is dedicated to the public.

1. An apparatus, comprising:
a finite state machine (FSM) having a data path and a clock path; and
circuitry separate from the FSM, the circuitry configured to:
receive a first analog signal;
receive a digital signal from the FSM and convert the digital signal to a second analog signal;
determine a comparison signal based on a difference between the first analog signal and the second analog signal; and
output the comparison signal to the FSM, wherein
the FSM is configured to:
receive the comparison signal from the circuitry;
generate an internal clock signal and output, via the clock path, the internal clock signal to the circuitry;
generate, via the data path, a comparator output based on the comparison signal and output the comparator output to the clock path;
generate, via the data path, the digital signal based on the comparator output and output the digital signal to the circuitry, the digital signal indicating output data;
generate, via the clock path, a comparison reset signal based on the internal clock signal and the comparator output when the comparator output reaches a threshold; and
output, via the clock path in response to generation of the comparison reset signal, the comparison reset signal to the circuitry.

2. The apparatus of claim 1, further comprising:,
a digital-to-analog converter configured to convert the digital signal to a converted analog signal, wherein
the circuitry is configured to determine the comparison signal based on a comparison between the analog signal and the converted analog signal.

3. (canceled)

4. The apparatus of claim 1, wherein the circuitry successively approximates the digital signal using a binary search.

5. The apparatus of claim 1, wherein the FSM comprises:
a pull-down circuit and an inverter configured to generate a rising edge of the internal clock signal; and
a pull-up block and a delay cell configured to generate a falling edge of the internal clock signal after the preset delay set by the delay cell.

6. The apparatus of claim 5, wherein
the pull-down block includes a pair of NMOS transistors, and
the pull-up block includes a PMOS transistor.

7. The apparatus of claim 1, wherein the FSM generates the internal clock signal using at least one parameter that is variable.

8. A method, comprising:
receiving, by circuitry, a first analog signal;
receiving, by the circuitry, a digital signal from a finite state machine (FSM), the FSM including a data path and a clock path;
converting, by the circuitry, the digital signal to a second analog signal;
determining, by the circuitry, a comparison signal based on a difference between the first analog signal and the second analog signal;
outputting, by the circuitry, the comparison signal to the FSM;
receiving, by the FSM, the comparison signal from the circuitry;
generating, via the clock path, an internal clock signal;
outputting, via the clock path, the internal clock signal to the circuitry;
generating, via the data path, a comparator output based on the comparison signal and output the comparator output to the clock path;
generating, via the data path, the digital signal based on the comparator output and output the digital signal to the circuitry, the digital signal indicating output data;
generating, via the clock path, a comparison reset signal based on the internal clock signal and the comparator output when the comparator output reaches a threshold; and
outputting, via the clock path in response to the generation of the comparison rest signal, the comparison reset signal to the circuitry.

9. The method of claim 8, further comprising:
converting the digital signal to a converted analog signal to determine the comparison signal based on a comparison between the analog signal and the converted analog signal.

10. (canceled)

11. The method of claim 8, further comprising:
successively approximating the digital signal using a binary search.

12. The method of claim 8, wherein the internal clock signal is generated by
generating a rising edge of the clock signal; and
generating a falling edge of the clock signal after the preset delay set by the delay cell.

13. The method of claim 8, wherein the internal clock signal is generated using at least one parameter that is variable.

14. A system, comprising:
a finite state machine (FSM) having a data path and a clock path; and
circuitry separate from the FSM, the circuitry configured to:
receive a digital signal from the FSM:
convert the digital signal to an analog signal, determine a comparison signal based on the analog signal; and
output the comparison signal to the FSM, wherein
the FSM is configured to:
receive the comparison signal from the circuitry;
generate an internal clock signal and output, via the clock path, the internal clock signal to the circuitry;
generate, via the data path, a comparator output based on the comparison signal and output the comparator output to the clock path;
generate, via the data path, the digital signal based on the comparator output and output the digital signal to the circuitry, the digital signal indicating output data;
generate, via the clock path, a comparison reset signal based on the internal clock signal and the comparator output when the comparator output reaches a threshold; and
output, via the clock path in response to generation of the comparison reset signal, the comparison reset signal to the circuitry.

15-16. (canceled)

17. The system of claim 14, wherein the circuitry successively approximates the digital signal using a binary search.

18. The system of claim 14, wherein the FSM comprises:
a pull-down circuit and an inverter configured to generate a rising edge of the clock signal; and
a pull-up block and a delay cell configured to generate a falling edge of the clock signal after the preset delay set by the delay cell.

19. The system of claim 18, wherein
the pull-down block includes a pair of NMOS transistors, and
the pull-up block includes a PMOS transistor.

20. The system of claim 14, wherein the finite state machine generates the internal clock signal using at least one parameter that is variable.
